(19) United States
(12) Patent Application Publication
(10) Pub. No.: US 2025/0226818 A1
(43) Pub. Date: Jul. 10, 2025

(54) Techniques For Routing Between A Network-On-Chip And Multiplexer Circuits In A Central Region Of An Integrated Circuit

(71) Applicant: Altera Corporation, San Jose, CA (US)

(72) Inventor: Przemek Guzy, Oakville (CA)

(73) Assignee: Altera Corporation, San Jose, CA (US)

(21) Appl. No.: 19/092,814

(22) Filed: Mar. 27, 2025

(51) Int. Cl. H03K 17/00

(52) U.S. Cl. CPC H03K 17/002

(57) ABSTRACT

An integrated circuit includes a central region having first multiplexer circuits and first busses that interconnect the first multiplexer circuits. The integrated circuit also includes a network-on-chip. The network-on-chip includes switch circuits, second multiplexer circuits, second busses that interconnect the switch circuits, third busses that interconnect the switch circuits and the second multiplexer circuits, and fourth busses that interconnect the first multiplexer circuits and the second multiplexer circuits. Each of the second multiplexer circuits is coupled to at least two of the switch circuits through a subset of the third busses.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data containing configuration bits. The configuration data is then loaded into configuration memory elements that configure configurable logic circuits in the integrated circuit to perform the functions of the custom circuit design. Configurable integrated circuits can be used for co-processing in big-data or fast-data applications. For example, configurable integrated circuits can be used in application acceleration tasks in a datacenter and can be reprogrammed during datacenter operation to perform different tasks.

### BRIEF DESCRIPTION OF DRAWINGS

FIG. 1 is a diagram that depicts an example of an integrated circuit (IC) that includes a network-on-chip (NOC) and a central fabric region in the IC.

FIG. 2 is a diagram that illustrates an example of a hybrid network-on-chip (NOC) configurable fabric routing architecture in an integrated circuit.

FIG. 3 is a diagram that illustrates another example of a hybrid network-on-chip (NOC) configurable fabric routing architecture in an integrated circuit.

FIG. 4 is a diagram of an illustrative example of a configurable integrated circuit (IC).

FIG. 5 illustrates a block diagram of a system that can be used to implement a circuit design to be programmed into a programmable logic device using design software.

FIG. 6 is a diagram that depicts an example of a programmable logic device that includes fabric dies and base dies that are connected to one another via microbumps.

FIG. 7 is a block diagram illustrating a computing system configured to implement one or more aspects of the embodiments described herein.

### DETAILED DESCRIPTION

Many configurable integrated circuits (ICs) have networks-on-chip (NOCs) that are used to transmit data across the ICs. In a typical NOC (network-on-chip) topology, a circuit designer provides enough cross sectional bandwidth in the NOC, so that the NOC can satisfy the maximum expected bandwidth of the expected connections to the NOC. Cross sectional bandwidth on the NOC is primarily achieved by adding additional wiring. As a result, overall NOC area is dominated by wires. A circuit designer carefully considers NOC connectivity and traffic between initiators and targets to and from the NOC. Designers of a configurable integrated circuit (IC) face the additional challenge of not knowing the connectivity and traffic pattern through a NOC in the IC, until the IC is configured. Consequently, a NOC in a configurable IC must be sized to be able to achieve the worst case bandwidth expected through the NOC, which often results in a NOC that is underutilized, and IC die area that is unused, in more typical usage cases.

A similar problem exists when budgeting for the number of fabric routing wires in a fabric region of a configurable IC. The length and the number of wires in the fabric routing are determined based on the routing requirements of the typical and worst case custom circuit designs. It is common for fabric routing wires to be underutilized in typical custom circuit designs for configurable ICs in order to satisfy the needs of worst case custom circuit designs.

According to some examples disclosed herein, a hybrid network-on-chip (NOC) configurable fabric routing architecture is provided with a shared set of routing conductors. Switches in the NOC and multiplexer circuits in the fabric routing can be configured to be used for routing either values for the NOC and/or for the fabric routing. A routing algorithm can optimally use conductors for NOC transport or fabric routing of signals. The hybrid NOC configurable fabric routing architecture eliminates the need to dedicate area to worst case NOC and worst case fabric routing scenarios in custom circuit designs for configurable ICs. The hybrid NOC configurable fabric routing architecture saves IC die area by sharing the conductors in the NOC and in the fabric routing. As an example, a custom circuit design for a configurable IC that heavily uses a NOC for transporting signals can route some of the signals through conductors in the routing fabric.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

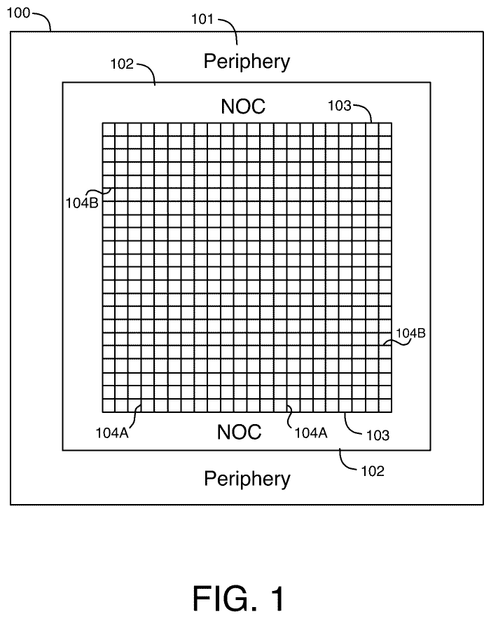

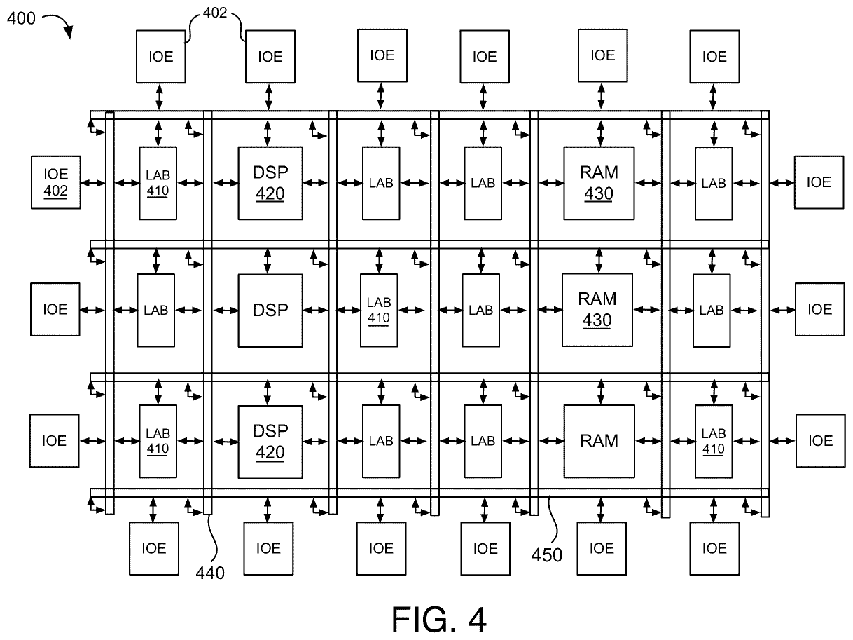

Figure (FIG.) 1 is a diagram that depicts an example of an integrated circuit (IC) 100 that includes a network-on-chip (NOC) 102 and a central fabric region 103 in the IC 100. The central fabric region 103 is also referred to herein as a central region or fabric region 103. The fabric region 103 includes vertical fabric routing busses 104A and horizontal fabric routing busses 104B that are arranged in a crisscrossing grid. Each of the fabric routing busses 104A and 104B includes several conductors routed in parallel. Although the fabric routing busses 104A-104B are arranged in a grid in the example of FIG. 1, it should be understood that ICs can include the hybrid network-on-chip (NOC) configurable fabric routing architecture disclosed herein with any arrangement of the fabric routing busses. The fabric region 103 also includes soft logic, hard logic, and memory circuits that are not shown in FIG. 1, but are shown, for example, in FIG. 4.

IC 100 also includes a periphery region 101 and a network-on-chip (NOC) 102 that surrounds the fabric region 103 and is inside the periphery region 101. The IC 100 of Figure (FIG.) 1 can be any type of integrated circuit (IC), such as a configurable IC (e.g., a field programmable gate array (FPGA) or programmable logic device (PLD)), a microprocessor IC, a graphics processing unit IC, a memory IC, an application specific IC, a transceiver IC, a memory IC, etc.

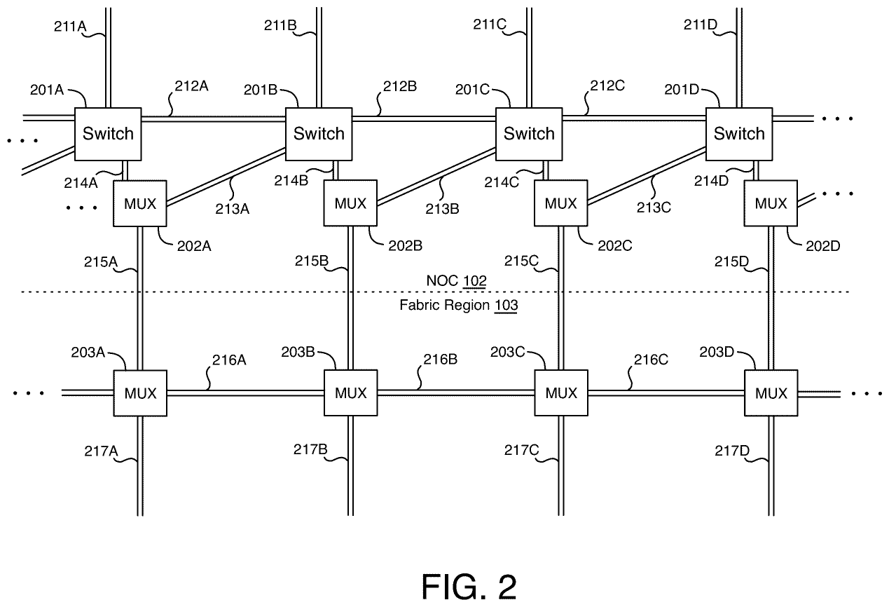

FIG. 2 is a diagram that illustrates an example of a hybrid network-on-chip (NOC) configurable fabric routing architecture in an integrated circuit. The hybrid network-on-chip (NOC) configurable fabric routing architecture of Figure (FIG. 2 includes the network-on-chip (NOC) 102 and the fabric region 103 in the IC 100 of FIG. 1. In the example of FIG. 2, the NOC 102 includes several switch circuits 201 and several multiplexer (MUX) circuits 202. Four switch circuits 201A, 201B, 201C, and 201D are shown in FIG. 2 as an example that is not intended to be limiting. Four multiplexer circuits 202A, 202B, 202C, and 202D are shown in FIG. 2 as an example that is not intended to be limiting. The fabric region 103 in IC 100 in the example of FIG. 2 includes several routing multiplexer (MUX) circuits 203. Four routing multiplexer circuits 203A, 203B, 203C, and 203D are shown in FIG. 2 as an example that is not intended to be limiting. According to various examples, IC 100 can include any number of switch circuits 201, multiplexer circuits 202, and routing multiplexer circuits 203. Each of the multiplexer circuits 202 and 203 is configurable.

The switch circuits 201 are coupled together through busses 212, such as busses 212A, 212B, and 212C, as shown in FIG. 2. The switch circuits 201 are coupled to the multiplexer circuits 202 through busses 213 and 214, such as busses 213A, 213B, 213C, 214A, 214B, 214C, and 214D, as shown in FIG. 2. Each of the busses 212, 213, and 214 includes several conductors (i.e., wires) routed in parallel with each other (e.g., 32, 64, 128, 256 etc. conductors). As examples, switch circuits 201A and 201B are coupled together through bus 212A, and switch circuits 201B and 201C are coupled together through bus 212B. As other examples, switch circuit 201A is coupled to multiplexer circuit 202A through bus 214A, and switch circuit 201B is coupled to multiplexer circuit 202B through bus 214B. As yet other examples, switch circuit 201B is coupled to multiplexer circuit 202A through bus 213A, and switch circuit 201C is coupled to multiplexer circuit 202B through bus 213B.

Routing multiplexer circuits 203 are coupled together through busses 216. As examples, routing multiplexer circuit 203A is coupled to routing multiplexer circuit 203B though bus 216A, and routing multiplexer circuit 203B is coupled to routing multiplexer circuit 203C through bus 216B. Routing multiplexer circuits 203 are coupled to multiplexer circuits 202 through busses 215. As examples, routing multiplexer circuit 203A is coupled to multiplexer circuit 202A through bus 215A, and routing multiplexer circuit 203B is coupled to multiplexer circuit 202B through bus 215B. Routing multiplexer circuits 203 are coupled to additional routing multiplexer circuits in the fabric region 103 of the IC 100 through busses 217. As examples, routing multiplexer circuit 203A is coupled to an additional routing multiplexer circuit through bus 217A, and routing multiplexer circuit 203B is coupled to an additional routing multiplexer circuit through bus 217B. Each of the busses 215, 216, and 217 includes several conductors (i.e., wires) routed in parallel with each other (e.g., 32, 64, 128, 256, etc. conductors). The busses 215-217 are part of the fabric routing busses 104A-104B.

The switch circuits 201 are also coupled to endpoint circuits (e.g., routing multiplexer circuits 203 or input/output circuits) in IC 100 through busses 211 (also referred to as bridges). As examples, switch circuit 201A is coupled to a first endpoint circuit (e.g., routing multiplexer circuit 203A or an input/output circuit) through bus 211A, switch circuit 201B is coupled to another endpoint circuit (e.g., routing multiplexer circuit 203B or an input/output circuit) through bus 211B, and switch circuit 201C is coupled to another endpoint circuit through bus 211C.

Each of the multiplexer circuits 202 and 203 is configurable to route one or more input values received from a source circuit through an input bus to a destination circuit through an output bus based on values of one or more select signals. Each of the multiplexer circuits 202 and 203 typically includes several smaller multiplexer circuits (e.g., many 2-to-1 multiplexer circuits) that are configurable to route input values from several source circuits received on input busses to several selected destination circuits through output busses. When IC 100 is configured, the routing multiplexer circuits 203 in the fabric region 103 are configured to route data from source circuits to destination circuits to form paths that can each include multiple vertical and/or horizontal routing busses. According to some examples, routing multiplexer circuits 203 are also configurable to route packets through the fabric region 103 and between multiplexer circuits 202.

Each of the switch circuits 201 is configurable to route packets to destination circuits in the IC. As an example, each of the switch circuits 201 can include a first-in-first-out (FIFO) buffer storage circuit that stores each packet received from an input bus. Each of the packets routed through the switch circuits 201 includes routing information and data (also referred to as packetized data). Each of the switch circuits 201 can also, for example, include a control circuit that examines each packet received from an input bus including the routing information in each packet. The control circuit in each switch circuit 201 can determine the destination circuit where each packet is to be sent based on the routing information in each packet and determine when to send each packet to the destination circuit. As examples, the control circuit in each switch circuit 201 can select the time to send each packet through an output bus based on priority settings in each packet and/or based on the amount of traffic currently being transmitted through one or more output busses coupled to the switch circuit.

In the example of FIG. 2, the multiplexer circuits 202 are added to the NOC 102 and coupled to the switch circuits 201, and the routing multiplexer circuits 203 are coupled to the additional multiplexer circuits 202, as described above. In some examples, the multiplexer circuits 202 are configurable to route data and other values between the routing multiplexer circuits 203 and the switch circuits 201 through the busses 213, 214, and 215. In these examples, one or more of the busses 213-215 in NOC 102 can be used to bypass a portion of the general fabric routing in fabric region 103. In these examples, the one or more busses 213-215 in NOC 102 are used for routing data and other values to and from the routing multiplexer circuits 203 in the fabric region 103 to bypass a portion of the fabric routing (e.g., one or more of busses 216). These examples can be used to significantly reduce data traffic and congestion in the fabric region 103, for example, through multiplexer circuits 203 and busses 216. These examples can also be used to significantly reduce the number of multiplexer circuits 203 and the number of conductors in busses 216 in IC 100.

The multiplexer circuits 202 are also configurable to route data and other values between the switch circuits 201 and the routing multiplexer circuits 203 through the busses 215 and 216. In these examples, one or more of the busses 216 in fabric region 103 can be used to bypass a portion of the NOC 102 by routing signals between multiplexer circuits 202 and 203 through busses 215 and between multiplexer circuits 203 though one or more of busses 216. These examples can be used to significantly reduce data traffic and congestion in the NOC 102 through switch circuits 201 and busses 212-214.

Each of the switch circuits 201 can include routing logic circuitry that is configurable to cause the switch circuit 201 to route packets between the switch circuits 201 through the busses 212. The routing logic circuitry is also configurable to cause packets to be routed between the switch circuits 201 through the multiplexer circuits 202 and the busses 213-214.

If IC 100 is a configurable IC, such as an FPGA or PLD, when a custom circuit design for the IC 100 is compiled, an optimizing router configures switch circuits 201, multiplexer circuits 202, and routing multiplexer circuits 203 based on timing of signals in the fabric region 103 and the topology and the utilization of the NOC 102 in the custom circuit design to reduce routing congestion in IC 100. Depending on the custom circuit design for IC 100, the switch circuits 201 and the multiplexer circuits 202-203 can be configured to route some packets from NOC 102 through multiplexer circuits 202-203 and busses 215-216 and then back to the NOC 102 through one or more busses 215. As a result, these packets bypass a portion of NOC 102 by being routed through the routing fabric in fabric region 103 before being routed back to NOC 102.

As an example, switch circuit 201A, multiplexer circuit 202A, routing multiplexer circuit 203A, routing multiplexer circuit 203B, multiplexer circuit 202B, and switch circuit 201B can be configured to route packets of data from switch circuit 201A to switch circuit 201B through busses 214A, 215A, 216A, 215B, and 214B to bypass NOC busses 212A and 213A. In this example, switch circuit 201A is configured to route packets through bus 214A to multiplexer circuit 202A. Multiplexer circuit 202A is configured to route the packets received from switch circuit 201A through bus 215A to multiplexer circuit 203A. Multiplexer circuit 203A is configured to route the packets received from multiplexer circuit 202A through bus 216A to multiplexer circuit 203B. Multiplexer circuit 203B is configured to route the packets received from multiplexer circuit 203A through bus 215B to multiplexer circuit 202B. Multiplexer circuit 202B is configured to route the packets received from multiplexer circuit 203B through bus 214B to switch circuit 201B. Switch circuit 201B is configured to route the packets received from multiplexer circuit 202B through the NOC 102 (e.g., to switch circuit 201C). NOC 102 can route other packets between switch circuits 201A and 201B through bus 212A.

As another example, switch circuit 201B, multiplexer circuit 202B, routing multiplexer circuit 203B, routing multiplexer circuit 203C, multiplexer circuit 202C, and switch circuit 201D can be configured to route packets of data from switch circuit 201B to switch circuit 201D through busses 214B, 215B, 216B, 215C, and 213C to bypass NOC busses 212B-212C and 213B. In this example, switch circuit 201B is configured to route packets through bus 214B to multiplexer circuit 202B. Multiplexer circuit 202B is configured to route the packets received from switch circuit 201B through bus 215B to multiplexer circuit 203B. Multiplexer circuit 203B is configured to route the packets received from multiplexer circuit 202B through bus 216B to multiplexer circuit 203C. Multiplexer circuit 203C is configured to route the packets received from multiplexer circuit 203B through bus 215C to multiplexer circuit 202C. Multiplexer circuit 202C is configured to route the packets received from multiplexer circuit 203C through bus 213C to switch circuit 201D. Switch circuit 201D is configured to route the packets received from multiplexer circuit 202C through the NOC 102. NOC 102 can route other packets between switch circuit 201B and switch circuit 201D through busses 212B-212C and switch circuit 201C.

According to other examples, the switch circuits 201 and the multiplexer circuits 202-203 can also be configured to route data and/or other values from fabric region 103 through multiplexer circuits 203 and 202, one or more switch circuits 201, and busses 215, 213, and 214, and then back to one or more routing multiplexer circuits 203 in the fabric region 103 through one or more of the busses 215. As a result, these values bypass one or more of busses 216 by being routed through the NOC 102 and then back to the fabric region 103 to reduce congestion in busses 216. The bypassed portions of busses 216 can still be used to route other signals.

As an example, routing multiplexer circuit 203A, multiplexer circuit 202A, switch circuit 201B, multiplexer circuit 202B, and routing multiplexer circuit 203B can be configured to route data values or other values from routing multiplexer circuit 203A to routing multiplexer circuit 203B through busses 215A, 213A, 214B, and 215B to bypass bus 216A. In this example, multiplexer circuit 203A is configured to route values of input signals through bus 215A to multiplexer circuit 202A. Multiplexer circuit 202A is configured to route the values received from multiplexer circuit 203A through bus 213A in NOC 102 to switch circuit 201B. Switch circuit 201B is configured to route the values received from multiplexer circuit 202A through bus 214B to multiplexer circuit 202B. Multiplexer circuit 202B is configured to route the values received from switch circuit 201B through bus 215B to multiplexer circuit 203B. Multiplexer circuit 203B is configured to route the values received from multiplexer circuit 202B through the fabric routing conductors (e.g., busses 216B or 217B). The values of other signals can be routed between multiplexer circuits 203A and 203B through bus 216A.

As another example, routing multiplexer circuit 203C, multiplexer circuit 202C, switch circuit 201D, multiplexer circuit 202D, and routing multiplexer circuit 203D can be configured to route data values or other values from routing multiplexer circuit 203C to routing multiplexer circuit 203D through busses 215C, 213C, 214D, and 215D to bypass bus 216C. In this example, multiplexer circuit 203C is configured to route values of input signals through bus 215C to multiplexer circuit 202C. Multiplexer circuit 202C is configured to route the values received from multiplexer circuit 203C through bus 213C in NOC 102 to switch circuit 201D. Switch circuit 201D is configured to route the values received from multiplexer circuit 202C through bus 214D to multiplexer circuit 202D. Multiplexer circuit 202D is configured to route the values received from switch circuit 201D through bus 215D to multiplexer circuit 203D. Multiplexer circuit 203D is configured to route the values received from multiplexer circuit 202D through the fabric routing conductors (e.g., bus 217D). The values of other signals can be routed between multiplexer circuits 203C and 203D through bus 216C.

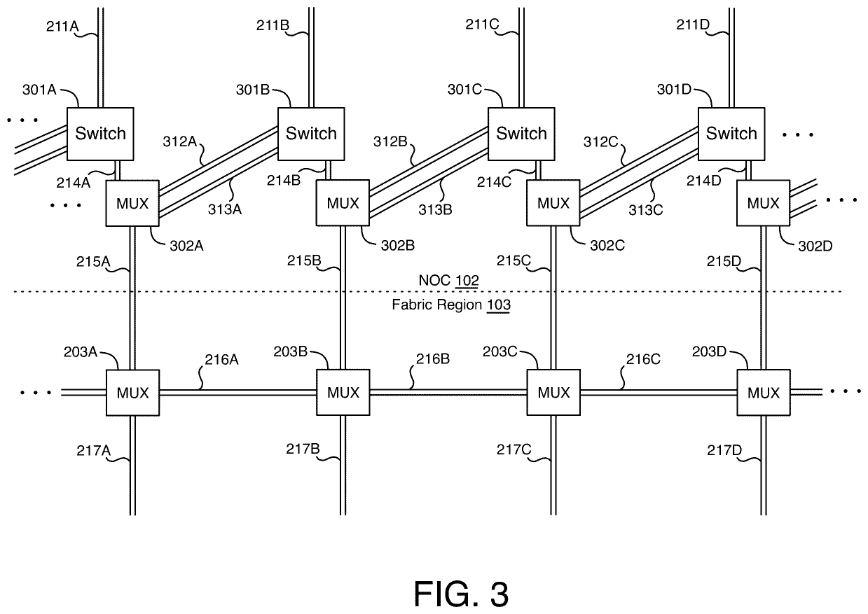

FIG. 3 is a diagram that illustrates another example of a hybrid network-on-chip (NOC) configurable fabric routing architecture in an integrated circuit. The hybrid NOC configurable fabric routing architecture of FIG. 3 includes the network-on-chip (NOC) 102 and the fabric region 103 in the IC 100 of FIG. 1. In the example of FIG. 3, the NOC 102 includes several switch circuits 301 and several multiplexer (MUX) circuits 302. Four switch circuits 301A, 301B, 301C, and 301D are shown in FIG. 3 as an example that is not intended to be limiting. Four multiplexer circuits 302A, 302B, 302C, and 302D are shown in FIG. 3 as an example that is not intended to be limiting. The fabric region 103 in IC 100 in the example of FIG. 3 includes the routing multiplexer (MUX) circuits 203 described above. According to various examples, IC 100 can include any number of switch circuits 301, multiplexer circuits 302, and routing multiplexer circuits 203. Each of the multiplexer circuits 302 and 203 is configurable.

The switch circuits 301 are coupled to multiplexer circuits 302 through busses 214 and 312-313, as shown in FIG. 3. Each of the busses 214 and 312-313 includes several conductors (i.e., wires) routed in parallel with each other. As examples, switch circuit 301B is coupled to multiplexer circuit 302A through busses 312A and 313A, and switch circuit 301C is coupled to multiplexer circuit 302B through busses 312B and 313B. As other examples, switch circuit 301A is coupled to multiplexer circuit 302A through bus 214A, and switch circuit 301B is coupled to multiplexer circuit 302B through bus 214B. The switch circuits 301 and the multiplexer circuits 302 are configurable to route packets between the switch circuits 301 through busses 214, 312, and/or 313 in the NOC. Each of the busses 312 and 313 may represent a separate channel or link between the switch circuits 301.

Routing multiplexer circuits 203 are coupled to multiplexer circuits 302 through busses 215. As examples, routing multiplexer circuit 203A is coupled to multiplexer circuit 302A through bus 215A, and routing multiplexer circuit 203B is coupled to multiplexer circuit 302B through bus 215B. Switch circuits 301 are also coupled to endpoint circuits (e.g., routing multiplexer circuits 203 or input/output circuits) in IC 100 through busses 211.

Switch circuits 301 and multiplexer circuits 302 and 203 can be configured to route packets from NOC 102 through multiplexer circuits 302 and 203 and busses 215-216, and then back to the NOC 102 through one or more busses 215. As a result, these packets bypass a portion of NOC 102 (including portions of busses 312-313) by being routed through the routing fabric in fabric region 103 before being routed back to NOC 102 to reduce congestion in NOC 102.

As an example, switch circuit 301A, multiplexer circuit 302A, routing multiplexer circuit 203A, routing multiplexer circuit 203B, multiplexer circuit 302B, and switch circuit 301C can be configured to route packets of data from switch circuit 301A to switch circuit 301C through busses 214A, 215A, 216A, 215B, and 312B or 313B to bypass NOC busses 312A and 313A. In this example, switch circuit 301A is configured to route packets through bus 214A to multiplexer circuit 302A. Multiplexer circuit 302A is configured to route the packets received from switch circuit 301A through bus 215A to multiplexer circuit 203A. Multiplexer circuit 203A is configured to route the packets received from multiplexer circuit 302A through bus 216A to multiplexer circuit 203B. Multiplexer circuit 203B is configured to route the packets received from multiplexer circuit 203A through bus 215B to multiplexer circuit 302B. Multiplexer circuit 302B is configured to route the packets received from multiplexer circuit 203B through bus 312B or 313B to switch circuit 301C. Switch circuit 301C is configured to route the packets received from multiplexer circuit 302B through the NOC 102 (e.g., to switch circuit 301D via multiplexer circuit 302C). NOC 102 can route other packets between switch circuits 301A and 301B through busses 214A, 312A, and 313A and multiplexer circuit 302A.

According to other examples, the switch circuits 301 and the multiplexer circuits 302 and 203 can be configured to route data or other values from fabric region 103 through multiplexer circuits 203 and 302, one or more switch circuits 301 in NOC 102, and busses 215, 312 and/or 313, and 214, and then back to one or more routing multiplexer circuits 203 in the fabric region 103 through one or more of the busses 215. As a result, these values bypass one or more of busses 216 by being routed through the NOC 102 and then back to the fabric region 103 to reduce routing congestion in fabric region 103. The bypassed portions of busses 216 can still be used to route other signals.

As an example, routing multiplexer circuit 203B, multiplexer circuit 302B, switch circuit 301C, multiplexer circuit 302C, and routing multiplexer circuit 203C can be configured to route data values or other values from routing multiplexer circuit 203B to routing multiplexer circuit 203C through busses 215B, 312B or 313B, 214C, and 215C to bypass bus 216B. In this example, multiplexer circuit 203B is configured to route values of input signals through bus 215B to multiplexer circuit 302B. Multiplexer circuit 302B is configured to route the values received from multiplexer circuit 203B through bus 312B and/or 313B in NOC 102 to switch circuit 301C. Switch circuit 301C is configured to route the values received from multiplexer circuit 302B through bus 214C to multiplexer circuit 302C. Multiplexer circuit 302C is configured to route the values received from switch circuit 301C through bus 215C to multiplexer circuit 203C. Multiplexer circuit 203C is configured to route the values received from multiplexer circuit 302C through the fabric routing conductors (e.g., busses 216C or 217C). The values of other signals can be routed between multiplexer circuits 203B and 203C through bus 216B.

FIG. 4 is a diagram of an illustrative example of a configurable integrated circuit (IC) 400. Configurable IC 400 is an example of an IC that can include the hybrid network-on-chip (NOC) configurable fabric routing architecture disclosed herein with respect to FIGS. 1-3. As shown in FIG. 4, the configurable integrated circuit 400 includes a two-dimensional array of configurable logic circuit blocks, including logic array blocks (LABs) 410 and other configurable logic circuit blocks, such as random access memory (RAM) blocks 430 and digital signal processing (DSP) blocks 420, for example. Configurable logic circuit blocks, such as LABs 410, can include smaller configurable regions (e.g., configurable logic elements, configurable logic blocks, or adaptive logic modules (ALMs)) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 (e.g., including IO circuit blocks) for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400).

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non- transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

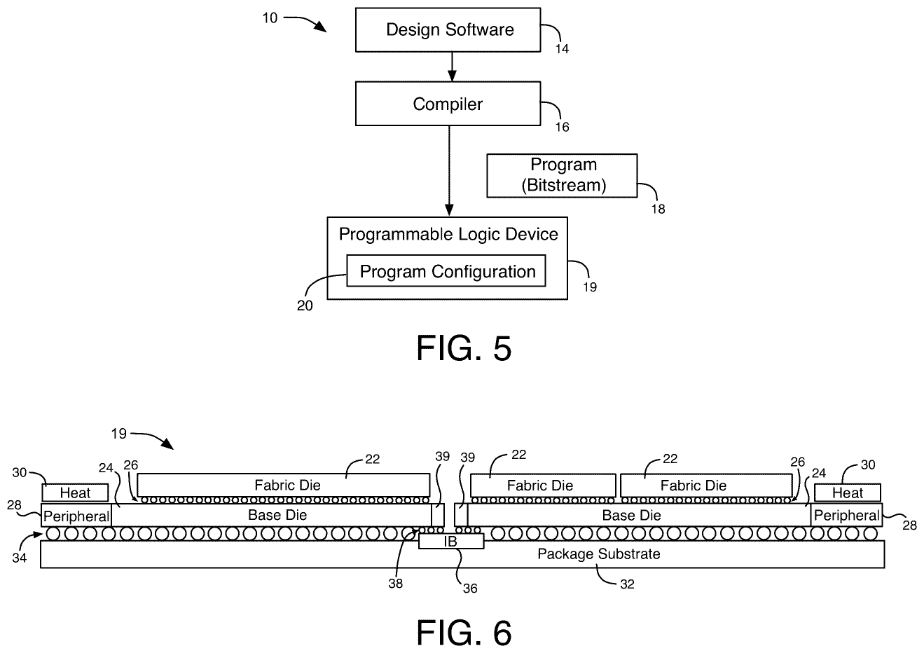

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

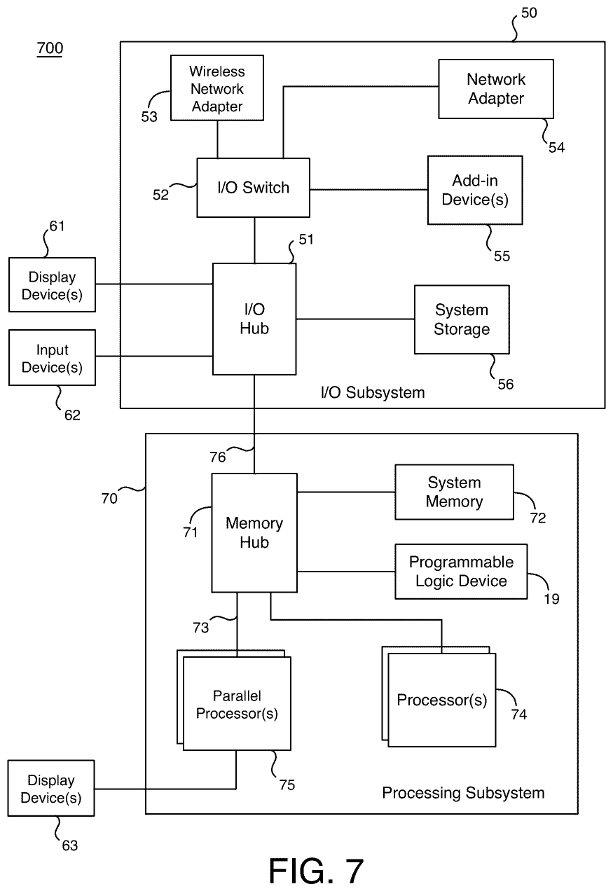

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising: a central region comprising first multiplexer circuits and first busses that interconnect the first multiplexer circuits; and a network-on-chip comprising switch circuits, second multiplexer circuits, second busses that interconnect the switch circuits, third busses that interconnect the switch circuits and the second multiplexer circuits, and fourth busses that interconnect the first multiplexer circuits and the second multiplexer circuits, and wherein each of the second multiplexer circuits is coupled to at least two of the switch circuits through a subset of the third busses.

In Example 2, the integrated circuit of Example 1 may optionally include, wherein the first and the second multiplexer circuits are configurable to route values from a first one of the switch circuits through a first one of the second multiplexer circuits, first and second ones of the first multiplexer circuits, and a second one of the second multiplexer circuits to a second one of the switch circuits to bypass one of the second busses.

In Example 3, the integrated circuit of Example 2 may optionally include, wherein the first one of the second multiplexer circuits is configurable to route the values received from the first one of the switch circuits via one of the third busses to the first one of the first multiplexer circuits via a first one of the fourth busses, and wherein the second one of the first multiplexer circuits is configurable to route the values received from the first one of the first multiplexer circuits via one of the first busses to the second one of the second multiplexer circuits via a second one of the fourth busses.

In Example 4, the integrated circuit of any one of Examples 1-3 may optionally include, wherein the first and the second multiplexer circuits are configurable to route values from a first one of the first multiplexer circuits through a first one of the second multiplexer circuits, one of the switch circuits, and a second one of the second multiplexer circuits to a second one of the first multiplexer circuits to bypass one of the first busses.

In Example 5, the integrated circuit of Example 4 may optionally include, wherein the first one of the second multiplexer circuits is configurable to route the values received from the first one of the first multiplexer circuits via a first one of the fourth busses to the one of the switch circuits via a first one of the third busses, and wherein the second one of the second multiplexer circuits is configurable to route the values received from the one of the switch circuits via a second one of the third busses to the second one of the first multiplexer circuits via a second one of the fourth busses.

In Example 6, the integrated circuit of any one of Examples 1-5 may optionally include, wherein each of the switch circuits comprises a control circuit that determines a destination circuit where a packet is to be sent based on routing information in the packet and that determines when to send the packet to the destination circuit.

In Example 7, the integrated circuit of any one of Examples 1-6 may optionally include, wherein each of the switch circuits comprises a first-in-first-out storage circuit that stores packets, and wherein each of the packets comprises data.

In Example 8, the integrated circuit of any one of Examples 1-7 may optionally include, wherein the network-on-chip further comprises fifth busses that interconnect the switch circuits and the second multiplexer circuits, and wherein each of the fifth busses is coupled in parallel with one of the third busses.

In Example 9, the integrated circuit of any one of Examples 1-8 may optionally include, wherein the integrated circuit is a configurable integrated circuit, and wherein the central region further comprises configurable logic circuit blocks coupled to the first busses.

Example 10 is a method for providing an integrated circuit that is configurable to bypass a portion of a network-on-chip to reduce routing congestion, the method comprising: providing a central region in the integrated circuit, wherein the central region comprises first multiplexer circuits and first busses that couple together the first multiplexer circuits; and providing the network-on-chip in the integrated circuit, wherein the network-on-chip comprises switch circuits, second multiplexer circuits, second busses that couple together the switch circuits, third busses that couple the switch circuits to the second multiplexer circuits, and fourth busses that couple the first multiplexer circuits to the second multiplexer circuits, and wherein each of the second multiplexer circuits is configurable to couple together at least two of the switch circuits through at least two of the third busses.

In Example 11, the method of Example 10 may optionally include, wherein each of the second multiplexer circuits is configurable to couple one of the switch circuits to one of the first multiplexer circuits through one of the fourth busses.

In Example 12, the method of any one of Examples 10-11 may optionally include, wherein a first one of the second multiplexer circuits is configurable to route values received from a first one of the switch circuits via one of the third busses to a first one of the first multiplexer circuits via a first one of the fourth busses, and wherein a second one of the first multiplexer circuits is configurable to route the values received from the first one of the first multiplexer circuits via one of the first busses to a second one of the second multiplexer circuits via a second one of the fourth busses.

In Example 13, the method of any one of Examples 10-12 may optionally include, wherein a first one of the second multiplexer circuits is configurable to route values received from a first one of the first multiplexer circuits via a first one of the fourth busses to one of the switch circuits via a first one of the third busses, and wherein a second one of the second multiplexer circuits is configurable to route the values received from the one of the switch circuits via a second one of the third busses to a second one of the first multiplexer circuits via a second one of the fourth busses.

In Example 14, the method of any one of Examples 10-13 may optionally include, wherein the network-on-chip further comprises fifth busses that couple the switch circuits to the second multiplexer circuits, and wherein each of the fifth busses is coupled in parallel with one of the third busses.

In Example 15, the method of any one of Examples 10-14 may optionally include, wherein each of the switch circuits comprises a control circuit that determines a destination circuit where a packet is to be sent based on routing information in the packet and that determines when to send the packet to the destination circuit.

Example 16 is an integrated circuit comprising: first conductors; a fabric region to transmit data through first multiplexer circuits across the integrated circuit; and a network-on-chip to transmit the data through switch circuits across the integrated circuit, wherein the first conductors are configurable to couple either the first multiplexer circuits or the switch circuits.

In Example 17, the integrated circuit of Example 16 may optionally include, wherein the first multiplexer circuits are configurable to bypass one of the switch circuits.

In Example 18, the integrated circuit of any one of Examples 16-17 may optionally include, wherein the network-on-chip comprises second multiplexer circuits that are configurable to bypass one of the first multiplexer circuits.

In Example 19, the integrated circuit of any one of Examples 16-18 may optionally include, wherein each adjacent pair of the switch circuits is coupled together through two channels in the network-on-chip.

In Example 20, the integrated circuit of any one of Examples 16-19 may optionally include, wherein each of the switch circuits comprises a first-in-first-out storage circuit that stores packets, and wherein each of the packets comprises data.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
a central region comprising first multiplexer circuits and first busses that interconnect the first multiplexer circuits; and
a network-on-chip comprising switch circuits, second multiplexer circuits, second busses that interconnect the switch circuits, third busses that interconnect the switch circuits and the second multiplexer circuits, and fourth busses that interconnect the first multiplexer circuits and the second multiplexer circuits, and wherein each of the second multiplexer circuits is coupled to at least two of the switch circuits through a subset of the third busses.

2. The integrated circuit of claim 1, wherein the first and the second multiplexer circuits are configurable to route values from a first one of the switch circuits through a first one of the second multiplexer circuits, first and second ones of the first multiplexer circuits, and a second one of the second multiplexer circuits to a second one of the switch circuits to bypass one of the second busses.

3. The integrated circuit of claim 2, wherein the first one of the second multiplexer circuits is configurable to route the values received from the first one of the switch circuits via one of the third busses to the first one of the first multiplexer circuits via a first one of the fourth busses, and wherein the second one of the first multiplexer circuits is configurable to route the values received from the first one of the first multiplexer circuits via one of the first busses to the second one of the second multiplexer circuits via a second one of the fourth busses.

4. The integrated circuit of claim 1, wherein the first and the second multiplexer circuits are configurable to route values from a first one of the first multiplexer circuits through a first one of the second multiplexer circuits, one of the switch circuits, and a second one of the second multiplexer circuits to a second one of the first multiplexer circuits to bypass one of the first busses.

5. The integrated circuit of claim 4, wherein the first one of the second multiplexer circuits is configurable to route the values received from the first one of the first multiplexer circuits via a first one of the fourth busses to the one of the switch circuits via a first one of the third busses, and wherein the second one of the second multiplexer circuits is configurable to route the values received from the one of the switch circuits via a second one of the third busses to the second one of the first multiplexer circuits via a second one of the fourth busses.

6. The integrated circuit of claim 1, wherein each of the switch circuits comprises a control circuit that determines a destination circuit where a packet is to be sent based on routing information in the packet and that determines when to send the packet to the destination circuit.

7. The integrated circuit of claim 1, wherein each of the switch circuits comprises a first-in-first-out storage circuit that stores packets, and wherein each of the packets comprises data.

8. The integrated circuit of claim 1, wherein the network-on-chip further comprises fifth busses that interconnect the switch circuits and the second multiplexer circuits, and wherein each of the fifth busses is coupled in parallel with one of the third busses.

9. The integrated circuit of claim 1, wherein the integrated circuit is a configurable integrated circuit, and wherein the central region further comprises configurable logic circuit blocks coupled to the first busses.

10. A method for providing an integrated circuit that is configurable to bypass a portion of a network-on-chip to reduce routing congestion, the method comprising:
providing a central region in the integrated circuit, wherein the central region comprises first multiplexer circuits and first busses that couple together the first multiplexer circuits; and
providing the network-on-chip in the integrated circuit, wherein the network-on-chip comprises switch circuits, second multiplexer circuits, second busses that couple together the switch circuits, third busses that couple the switch circuits to the second multiplexer circuits, and fourth busses that couple the first multiplexer circuits to the second multiplexer circuits, and wherein each of the second multiplexer circuits is configurable to couple together at least two of the switch circuits through at least two of the third busses.

11. The method of claim 10, wherein each of the second multiplexer circuits is configurable to couple one of the switch circuits to one of the first multiplexer circuits through one of the fourth busses.

12. The method of claim 10, wherein a first one of the second multiplexer circuits is configurable to route values received from a first one of the switch circuits via one of the third busses to a first one of the first multiplexer circuits via a first one of the fourth busses, and wherein a second one of the first multiplexer circuits is configurable to route the values received from the first one of the first multiplexer circuits via one of the first busses to a second one of the second multiplexer circuits via a second one of the fourth busses.

13. The method of claim 10, wherein a first one of the second multiplexer circuits is configurable to route values received from a first one of the first multiplexer circuits via a first one of the fourth busses to one of the switch circuits via a first one of the third busses, and wherein a second one of the second multiplexer circuits is configurable to route the values received from the one of the switch circuits via a second one of the third busses to a second one of the first multiplexer circuits via a second one of the fourth busses.

14. The method of claim 10, wherein the network-on-chip further comprises fifth busses that couple the switch circuits to the second multiplexer circuits, and wherein each of the fifth busses is coupled in parallel with one of the third busses.

15. The method of claim 10, wherein each of the switch circuits comprises a control circuit that determines a destination circuit where a packet is to be sent based on routing information in the packet and that determines when to send the packet to the destination circuit.

16. An integrated circuit comprising:
first conductors;
a fabric region to transmit data through first multiplexer circuits across the integrated circuit; and
a network-on-chip to transmit the data through switch circuits across the integrated circuit, wherein the first conductors are configurable to couple either the first multiplexer circuits or the switch circuits.

17. The integrated circuit of claim 16, wherein the first multiplexer circuits are configurable to bypass one of the switch circuits.

18. The integrated circuit of claim 16, wherein the network-on-chip comprises second multiplexer circuits that are configurable to bypass one of the first multiplexer circuits.

19. The integrated circuit of claim 16, wherein each adjacent pair of the switch circuits is coupled together through two channels in the network-on-chip.

20. The integrated circuit of claim 16, wherein each of the switch circuits comprises a first-in-first-out storage circuit that stores packets, and wherein each of the packets comprises data.
